(19) United States
(12) Patent Application Publication
(10) Pub. No.: US 2026/0088757 A1
(43) Pub. Date: Mar. 26, 2026

(54) IV DETECTION MECHANISM FOR 0BB SILICON WAFERS

(71) Applicant: Guangdong Kelongwei Automation Equipment Co., Ltd., Dongguan (CN)

(72) Inventors: Chunfu CHEN, Dongguan (CN); Jincai SU, Dongguan (CN)

(21) Appl. No.: 19/403,600

(22) Filed: Nov. 28, 2025

(30) Foreign Application Priority Data
Nov. 28, 2024 (CN) 202411727428.6

(51) Int. Cl. H02S 50/10; G01R 1/04; G01R 1/067

(52) U.S. Cl. CPC H02S 50/10; G01R 1/04; G01R 1/06705

(57) ABSTRACT

The invention discloses an IV detection mechanism for 0BB silicon wafers, including two detection modules, both comprise a UVW base, a gold wire row test frame and a silver row test frame; the gold wire row test frame and the silver row test frame respectively move on the UVW base along the vertical direction; gold wires are installed on the gold wire row and silver rows are installed on the silver row test frame; the two detection modules move independently. In the IV inspection mechanism for 0BB silicon wafers, the double half-cells independently carry out 0BB IV inspection, so that both sides can independently lift up and down, and correction alignment can be performed in the UVW direction, so that the gold wires and silver rows are accurately aligned with the grid lines on the half-cell, the inspection efficiency is improved, and the productivity is increased.

### CROSS-REFERENCE TO RELATED APPLICATIONS

This application claims the benefit of priority from Chinese Patent Application No. 202411727428.6, filed on Nov. 28, 2024. The content of the aforementioned applications, including any intervening amendments thereto, is incorporated herein by reference.

### TECHNICAL FIELD

The present invention relates to the technical field of silicon wafer production, particularly to an IV detection mechanism for 0BB silicon wafers.

### BACKGROUND

Photovoltaic solar silicon wafers (hereinafter referred to as silicon wafers) constitute the core component of solar power generation systems and represent the most valuable part of solar power generation systems. The function of silicon wafers is to convert solar energy into electrical energy, and then electrical energy is stored in batteries or directly powers loads. In existing silicon wafers, the front side has a main grid line, the main grid line will block the surface of the solar cell, affecting the light absorption of the solar cell, and then affecting the power generation efficiency. In subsequent new silicon wafers, cancellation of the main grid line on the front side makes it difficult to detect the quality of the silicon wafer in the production process and affects the detection of the yield. Moreover, in order to dock the production of the double half-cells, it is necessary to carry out the IV detection of the double half-cells.

### SUMMARY

An objective of the present invention is to provide an IV detection mechanism for 0BB silicon wafers, wherein it can reduce the cost and increase the efficiency of OBB silicon wafers during the use of silicon wafers, and furthermore, adopts a double half-cell IV detection structure with independent sides to realize the electrical performance detection and reduce the fragmentation rate.

To achieve this objective, the present invention employs the following technical solutions:

An IV detection mechanism for 0BB silicon wafers, including a left detection module and a right detection module, the left detection module and the right detection module both comprise a UVW base, a gold wire row test frame and a silver row test frame; the lower end of the UVW base is provided with a UVW correction alignment assembly, and the UVW correction alignment assembly comprises two sets of X-axis modules and one set of Y-axis modules; the gold wire row test frame and the silver row test frame respectively move on the UVW base along the vertical direction; gold wires are installed on the gold wire row and silver rows are installed on the silver row test frame; the left detection module and the right detection module move independently of each other.

As a preferred technical solution, a lifting support is installed on the UVW base, an upper linear module and a lower linear module are arranged on the lifting support, the driving end of the upper linear module is connected with an upper mounting frame, the gold wire row is fixed in the upper mounting frame, the driving end of the lower linear module is connected with a lower mounting frame, and the silver row test frame is fixed in the lower mounting frame.

As a preferred technical solution, both sides of the gold wire row are provided with tension springs, both ends of the gold wire are fixed on the tension springs, and the gold wire is connected with an upper lead.

As a preferred technical solution, a circuit board is fixed outside the gold wire row, and the upper lead is connected to the circuit board.

As a preferred technical solution, both sides of the silver row test frame are provided with mounting grooves, the ends of the silver row are inserted into the mounting grooves, and a pressing strip is arranged above the mounting grooves, the pressing strip is pressed on the ends of the silver row, the upper end of the silver row is curved upwards to form an arc, and the silver row is connected with a lower lead.

As a preferred technical solution, the upper linear module comprises an upper motor, an upper screw rod and an upper nut, the upper motor is connected with the lower end of the upper screw rod, the upper screw rod is in threaded connection with the upper nut, and the upper mounting frame is fixedly connected with the upper nut after passing through the lifting support.

As a preferred technical solution, the lower linear module comprises a lower motor, a lower screw rod and a lower nut, the lower motor is connected with the upper end of the lower screw rod, the lower screw rod is in threaded connection with the lower nut, and the lower mounting frame is fixedly connected with the lower nut after passing through the lifting support.

As a preferred technical solution, vertical sliders are connected to the outer sides of the upper mounting frame and the lower mounting frame, vertical sliding rails are fixed on the lifting support along the vertical direction, and the vertical sliders slide on the vertical sliding rails.

As a preferred technical solution, the X-axis module and the Y-axis module both comprise a motor mounting base, a module motor, an adjusting screw rod and an adjusting sliding table. The module motor is fixed on the motor mounting base, the driving end of the module motor is in transmission connection with the adjusting screw rod, and the adjusting screw rod is in threaded connection with the adjusting nut of the adjusting sliding table. The adjusting sliding table slides along the length direction of the adjusting screw rod, and the adjusting sliding table is provided with a connecting bearing; the connecting bearing slides on the adjusting sliding table, the moving direction of the connecting bearing is perpendicular to that of the adjusting sliding table, and the edge of the UVW base is locked in the connecting bearing; two sets of X-axis modules and one set of Y-axis modules jointly control the T-axis rotation of the UVW base on one side.

As a preferred technical solution, linear guide rails and linear sliders are used for sliding connection between the adjusting sliding table and the connecting bearing, and between the adjusting sliding table and the motor mounting base.

The beneficial effects of present invention: An IV detection mechanism for 0BB silicon wafers is provided; double half-cells in the IV detection mechanism for 0BB silicon wafers independently carry out 0BB IV inspection, so that both sides can independently lift up and down, and correction alignment can be performed in the UVW direction, so that the gold wires and silver rows are accurately aligned with the grid lines on the half-cell, the inspection efficiency is improved, and the productivity is increased.

### BRIEF DESCRIPTION OF THE DRAWINGS

The present invention will now be described in further detail with reference to the drawings and embodiments.

FIG. 1 is an overall structural diagram of an IV inspection mechanism for 0BB silicon wafers according to Embodiment 1;

FIG. 2 is a structural diagram of the gold wire row according to the embodiment;

FIG. 3 is a structural diagram of the silver row test frame according to the embodiment;

FIG. 4 is a structural diagram of the X-axis module (or Y-axis module) according to the embodiment;

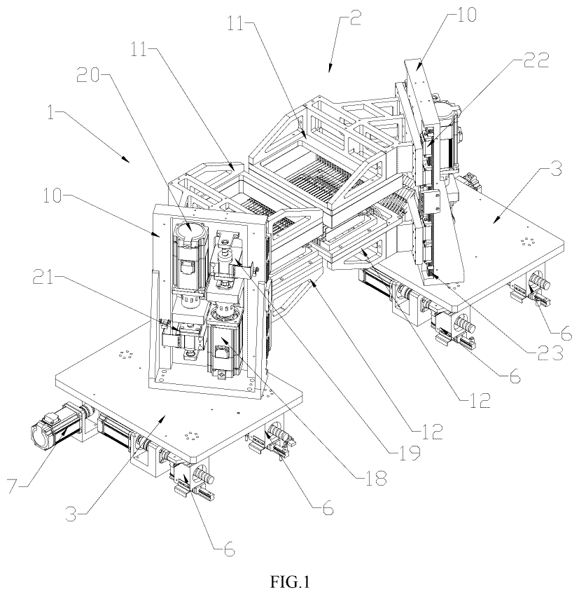

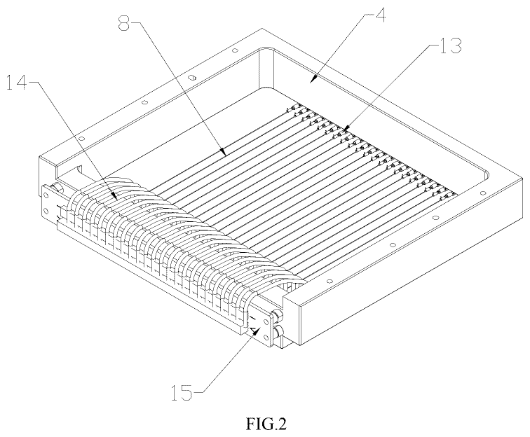

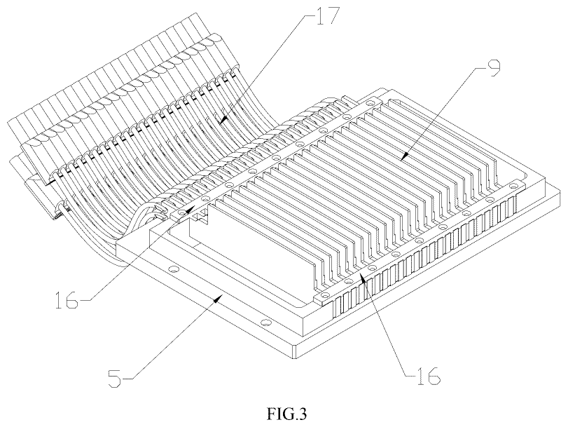

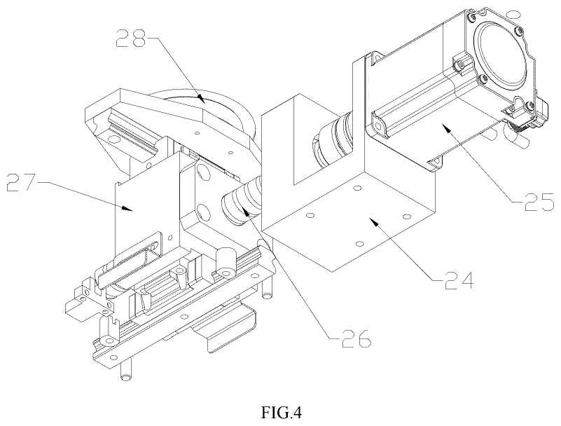

In FIG. 1 to FIG. 4:

1. Left detection module; 2. Right detection module; 3. UVW base; 4. Gold wire row; 5. Silver row test frame; 6. X-axis module; 7. Y-axis module; 8. Gold wire; 9. Silver wire row; 10. Lifting support; 11. Upper mounting frame; 12. Lower mounting frame; 13. Tension spring; 14. Upper lead; 15. Circuit board; 16. Pressing strip; 17. Lower lead; 18. Upper motor; 19. Upper nut; 20. Lower motor; 21. Lower nut; 22. Vertical slider; 23. Vertical sliding rail; 24. Motor mounting base; 25. Module motor; 26. Adjusting screw rod; 27. Adjusting sliding table; 28. Connecting bearing.

### DETAILED DESCRIPTION OF EMBODIMENTS

The technical solution of the present invention will be further explained by specific embodiments with reference to the attached drawings.

As shown in FIG. 1 to FIG. 4, in this embodiment, an IV detection mechanism for 0BB silicon wafers includes a left detection module 1 and a right detection module 2. Both the left detection module 1 and the right detection module 2 include a UVW base 3, a gold wire row 4 and a silver row test frame 5. The lower end of the UVW base 3 is installed with a UVW correction alignment assembly, the UVW correction alignment assembly includes two sets of X-axis modules 6 and one set of Y-axis modules 7. The gold wire row 4 and the silver row test frame 5 move vertically on the UVW base 3 respectively. The gold wire 8 is installed on the gold wire row 4, and the silver row 9 is installed on the silver row test frame 5. The left detection module 1 and the right detection module 2 move independently of each other.

0BB silicon wafers of the double half-cellscome to the left detection module 1 and the right detection module 2 respectively. Under the action of UVW correction alignment assembly, two sets of X-axis modules 6 and one set of Y-axis modules 7 work together, so that the UVW base 3 can move in the X-axis direction, Y-axis direction and T-axis rotation angle, then the gold wire row 4 and the silver row test frame 5 are controlled to align with the position of the half silicon wafer, and then the gold wire row 4 moves downward, the silver row test frame 5 moves upward, and the gold wire 8 is pressed on the auxiliary grid. After the silver row 9 is placed under the auxiliary grid of the half-cell 0BB silicon wafer to form a path, electrical performance can be tested.

A lifting support 10 is installed on the UVW base 3, and the lifting support 10 is provided with an upper linear module and a lower linear module. The driving end of the upper linear module is connected with an upper mounting frame 11, and the driving end of the lower linear module is connected with a lower mounting frame 12. The silver row test frame 5 is fixed in the lower mounting frame 12. When controlling the lifting of the gold wire row 4, the upper linear module moves up and down to control the lifting of the silver row test frame 5.

The two sides of the gold wire row 4 are provided with tension springs 13, both ends of the gold wire 8 are fixed on the tension springs 13, the gold wire 8 is connected with an upper lead 14, the outer side of the gold wire row 4 is fixed with a circuit board 15, and the upper lead 14 is connected to the circuit board 15. Under the action of the tension spring 13, the gold wire 8 assumes an elastic state and is screwed on the gold wire row 4 to prevent hard contact with half-cells, and the docking of electric signals depends on the circuit board 15 for receiving.

Both sides of the silver row test frame 5 are provided with mounting grooves, and the end of the silver row 9 is inserted into the mounting groove. A pressing strip 16 is arranged above the mounting groove, and the pressing strip 16 presses on the end of the silver row 9. The upper end of the silver row 9 is in an upward bending arc, and the silver row 9 is connected with a lower lead 17. The upward bending arc structure can accurately push the silver row 9 against the middle of the auxiliary grid, and the silver row 9 is fixed by the pressing strips 16 on both sides during installation.

The upper linear module includes an upper motor 18, an upper screw rod and an upper nut 19, wherein the upper motor 18 is connected with the lower end of the upper screw rod, the upper screw rod is in threaded connection with the upper nut 19, and the upper mounting frame 11 is fixedly connected with the upper nut 19 after passing through the lifting support 10; the lower linear module comprises a lower motor 20, a lower screw rod and a lower nut 21, wherein the lower motor 20 is connected with the upper end of the lower screw rod, the lower screw rod is screwed with the lower nut 21, and the lower mounting frame 12 is fixedly connected with the lower nut 21 after passing through the lifting support 10; the up-and-down installation of the upper linear module and the lower linear module is just symmetrical and opposite, and the rotation of the nut is controlled by the motor through the screw rod to realize the lifting of the mounting frame, and the corresponding gold wire row 4 and silver row test frame 5 can be lifted.

A vertical slider 22 is connected to the outer side of the upper mounting frame 11 and the outer side of the lower mounting frame 12, and a vertical sliding rail 23 is fixed on the lifting support 10 along the vertical direction. The vertical slider 22 slides on the vertical slide rail 23, and when the upper mounting frame 11 and the lower mounting frame 12 are lifted, the vertical sliding rail 22 and the vertical sliding rail 23 conduct wires and reduce friction.

Both the X-axis module 6 and the Y-axis module 7 include a motor mounting base 24, a module motor 25, an adjusting screw rod 26 and an adjusting sliding table 316. The module motor 25 is fixed on the motor mounting base 24, and the driving end of the module motor 25 is in transmission connection with the adjusting screw rod 26, wherein the adjusting screw rod 26 is in threaded connection with an adjusting nut of the adjusting sliding table 27, and the adjusting sliding table 27 slides along the length direction of the adjusting screw rod 26. The adjusting sliding table 27 has a connecting bearing 28, and the connecting bearing 28 slides on the adjusting sliding table 27. The moving direction of the connecting bearing 28 is perpendicular to the moving direction of the adjusting sliding table 27, and the edge of the UVW base 3 is locked in the connecting bearing 28. The two sets of X-axis modules 6 and one set of Y-axis modules 7 jointly control the T-axis rotation of the UVW base 3 on one side. linear guide rails and linear sliders are used for sliding connection between the adjusting sliding table 27 and the connecting bearing 28, and between the adjusting sliding table 27 and the motor mounting base 24.

The UVW correction alignment assembly 5 is a high-precision motion structure specifically designed for high-precision alignment equipment. Commonly referred to as an XXY platform, this three-axis parallel movement mechanism achieves rotational motion centered at any point on a plane and translation in any direction (in-plane three-axis X, Y, θ motion) by controlling the parallel movement of three linear motion structures. When integrated with the vision module, the UVW correction alignment assembly 5 delivers high-precision alignment capabilities suitable for silicon wafer printing applications.

More specifically, the implementation process of the UVW correction alignment assembly involves determining the transformation matrix from the camera coordinate system to the UVW platform coordinate system through visual calibration. The marker template obtains the x, y, and θ offsets between the marker template position and the marker to be corrected (based on the origin coordinate system of the UVW correction alignment assembly) based on the coordinate values of the origin coordinate system of the UVW correction alignment assembly through the visual module. Then, after the initial coordinates of the three axes are input according to the formula, the rotation center is set to (0,0), and the θ offset is input, the new coordinate values of the UVW three axes, the new coordinates of the object to be corrected, and the feed amounts corresponding to the three motors can be obtained. The series operations decompose the motion process into translation and rotation components, and calculate the motor feed amounts separately to achieve precise automatic positioning with alignment accuracy reaching the micron order.

It should be noted that the above specific implementation methods merely represent preferred embodiments of the present invention and the technical principles employed. Within the scope of the disclosed technology, any modifications or substitutions readily conceivable by those skilled in the art should be encompassed within the scope of protection of the present invention.

What is claimed is:

1. An IV detection mechanism for 0BB silicon wafers, wherein it includes a left detection module and a right detection module, the left detection module and the right detection module both comprise a UVW base, a gold wire row test frame and a silver row test frame; the lower end of the UVW base is provided with a UVW correction alignment assembly, and the UVW correction alignment assembly comprises two sets of X-axis modules and one set of Y-axis modules; the gold wire row test frame and the silver row test frame respectively move on the UVW base along the vertical direction;
gold wires are installed on the gold wire row and silver rows are installed on the silver row test frame; the left detection module and the right detection module move independently of each other.

2. An IV inspection mechanism for 0BB silicon wafers as claimed in claim 1, wherein a lifting support is installed on the UVW base, an upper linear module and a lower linear module are arranged on the lifting support, the driving end of the upper linear module is connected with an upper mounting frame, the gold wire row is fixed in the upper mounting frame, the driving end of the lower linear module is connected with a lower mounting frame, and the silver row test frame is fixed in the lower mounting frame.

3. An IV inspection mechanism for 0BB silicon wafers as claimed in claim 1, wherein both sides of the gold wire row are provided with tension springs, both ends of the gold wire are fixed on the tension springs, and the gold wire is connected with an upper lead.

4. An IV inspection mechanism for 0BB silicon wafers as claimed in claim 3, wherein a circuit board is fixed outside the gold wire row, and the upper lead is connected to the circuit board.

5. An IV inspection mechanism for 0BB silicon wafers as claimed in claim 1, wherein both sides of the silver row test frame are provided with mounting grooves, the ends of the silver row are inserted into the mounting grooves, and a pressing strip is arranged above the mounting grooves, the pressing strip is pressed on the ends of the silver row, the upper end of the silver row is curved upwards to form an arc, and the silver row is connected with a lower lead.

6. An IV inspection mechanism for 0BB silicon wafers as claimed in claim 2, wherein the upper linear module comprises an upper motor, an upper screw rod and an upper nut, the upper motor is connected with the lower end of the upper screw rod, the upper screw rod is in threaded connection with the upper nut, and the upper mounting frame is fixedly connected with the upper nut after passing through the lifting support.

7. An IV inspection mechanism for 0BB silicon wafers as claimed in claim 2, wherein the lower linear module comprises a lower motor, a lower screw rod and a lower nut, the lower motor is connected with the upper end of the lower screw rod, the lower screw rod is in threaded connection with the lower nut, and the lower mounting frame is fixedly connected with the lower nut after passing through the lifting support.

8. An IV inspection mechanism for 0BB silicon wafers as claimed in claim 2, wherein vertical sliders are connected to the outer sides of the upper mounting frame and the lower mounting frame, vertical sliding rails are fixed on the lifting support along the vertical direction, and the vertical sliders slide on the vertical sliding rails.

9. An IV inspection mechanism for 0BB silicon wafers as claimed in claim 1, wherein the X-axis module and the Y-axis module both comprise a motor mounting base, a module motor, an adjusting screw rod and an adjusting sliding table. The module motor is fixed on the motor mounting base, the driving end of the module motor is in transmission connection with the adjusting screw rod, and the adjusting screw rod is in threaded connection with the adjusting nut of the adjusting sliding table. The adjusting sliding table slides along the length direction of the adjusting screw rod, and the adjusting sliding table is provided with a connecting bearing; the connecting bearing slides on the adjusting sliding table, the moving direction of the connecting bearing is perpendicular to that of the adjusting sliding table, and the edge of the UVW base is locked in the connecting bearing; two sets of X-axis modules and one set of Y-axis modules jointly control the T-axis rotation of the UVW base on one side.

10. An IV inspection mechanism for 0BB silicon wafers as claimed in claim 9, wherein linear guide rails and linear sliders are used for sliding connection between the adjusting sliding table and the connecting bearing, and between the adjusting sliding table and the motor mounting base.
